(19) United States
(12) Patent Application Publication
(10) Pub. No.: US 2008/0017991 A1
(43) Pub. Date: Jan. 24, 2008

(54) SEMICONDUCTOR CHIP

(76) Inventor: Jin-Han Kim, Gyeongi-do (KR)

Correspondence Address: SHERR & NOURSE, PLLC, 620 HERNDON PARKWAY, SUITE 200, HERNDON, VA, 20170, US

(21) Appl. No.: 11/778,431

(22) Filed: Jul. 16, 2007

(30) Foreign Application Priority Data
Jul. 21, 2006 (KR) 10-2006-0068719

(51) Int. Cl. H01L 23/48; H01L 21/4763

(52) U.S. Cl. 257/773; 438/612; 257/E23.01; 257/E21.495

(57) ABSTRACT

A semiconductor chip may include a conductive pad to connect a semiconductor device to an external circuit. At least one semiconductor device may be formed on a semiconductor substrate. At least one metal wiring layer may be formed over at least one semiconductor device. The plurality of metal wiring layers may provide electrical connections to semiconductor devices on the semiconductor chip. At least one metal wiring layer may have a portion that is open in the center of the metal wiring layer. At least one interlayer dielectric layer may be formed between the semiconductor device and the conductive pad. At least one of the interlayer dielectric layers fills an open portion of a metal wiring layer.

The present application claims priority under 35 U.S.C. 119 to Korean Patent Application No. 10-2006-068719 (filed on Jul. 21, 2006), which is hereby incorporated by reference in its entirety.

### BACKGROUND

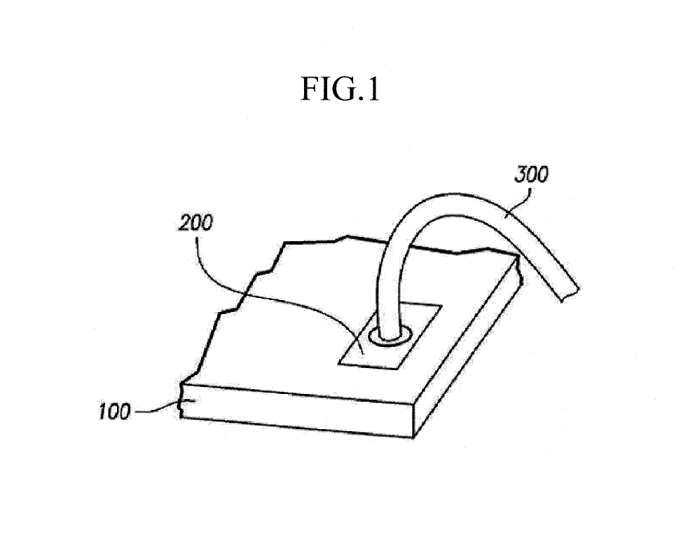

A plurality of semiconductor devices may be formed in a semiconductor chip. The plurality of semiconductor devices may be electrically connected to an external circuit by a conductive pad formed on an upper surface of the chip. Example FIG. 1 illustrates semiconductor chip 100 including a conductive pad 200 connected to an external circuit (e.g. a lead frame) through a bonding wire 300.

A plurality of semiconductor circuit devices (e.g. MOS transistors) may be formed on a semiconductor substrate and a plurality of metal wiring layers may be formed in order to provide electrical connection to these circuit devices. A plurality of interlayer dielectric layers may be formed for isolating the unit circuit device and the metal wiring layer from each other. Respective unit circuit devices and metal wiring layers may be electrically connected to each other by a plurality of contact plugs penetrating the interlayer dielectric layer.

A chip pad on the upper surface of the semiconductor chip may be electrically connected to an external circuit. The chip pad may also be electrically connected to a metal wiring layer (e.g. an uppermost wiring layer) through contact plugs penetrating an interlayer dielectric layer. Accordingly, a plurality of semiconductor devices formed on a semiconductor substrate may be connected to an external circuit through contact plugs, at least one metal wiring layer, and a chip pad.

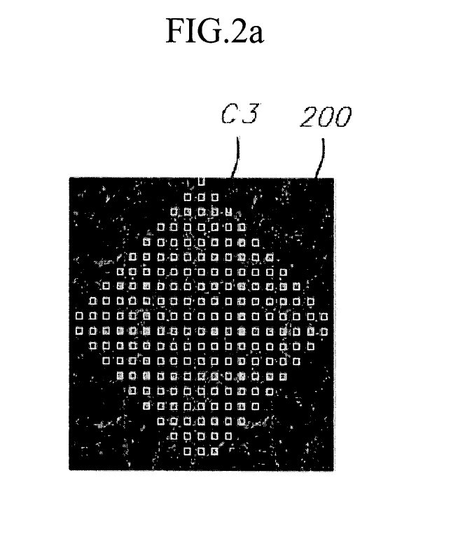

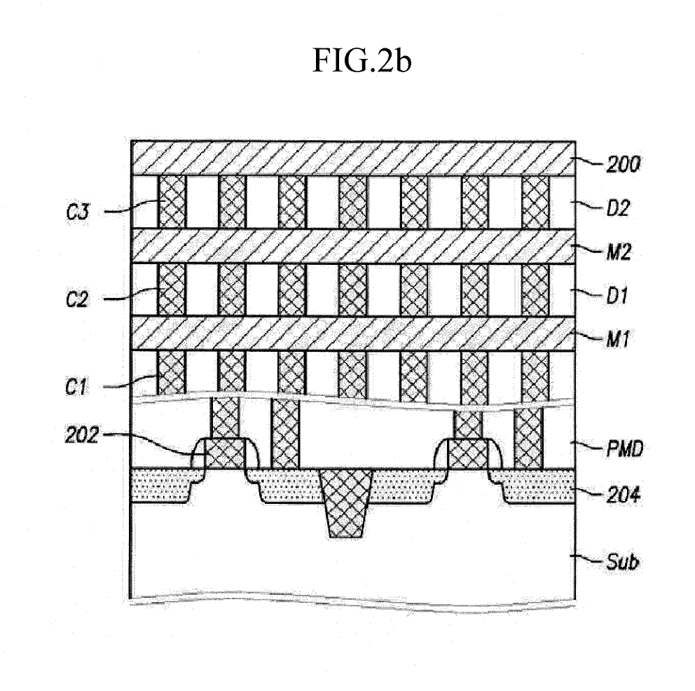

Example FIGS. 2a and 2b illustrate a chip pad, a plurality of metal wiring layers, and a plurality of interlayer dielectric layer below the chip pad. Example FIG. 2a illustrates a plurality of contact plugs C3 electrically connected to a metal wiring layer underneath the contact plugs C3. Example FIG. 2b illustrates a cross section of a semiconductor chip including a semiconductor device formed on a semiconductor substrate. As illustrated in FIG. 2a, a plurality of contact plugs C3 may be arranged directly below the chip pad 200 in the formation of a lozenge and/or a square.

As illustrated in example FIG. 2b, contact plugs C3 may be connected to metal wiring layer M2. Metal wiring layer M2 may be connected to first metal wiring layer M1 by contact plugs C2. Chip pad 200, metal wiring layer M1, and metal wiring layer M2 may be isolated by interlayer dielectric layer D1 and interlayer dielectric layer D2.

First metal wiring layer M1 may be isolated from a semiconductor device by polysilicon-metal dielectric (PMD). First metal wiring layer M1 may be connected to a gate electrode 202 or a source/drain diffusion region 204 of a transistor by contact plugs C1.

The semiconductor chip may be tested for reliability and performance through electrical connection to an external device through chip pad 200. An external device may be connected to chip pad 200 through wire bonding prior to the formation of a package that will house the final semiconductor product. During testing, a relatively large load may be applied to a chip pad by a probe. An oxide film may be used as an insulating layer between semiconductor devices and metal wiring layers. However, oxide may be relatively weak from a material standpoint and may crack.

Cracking caused by an excessive load on a chip pad during testing may cause cracks in an interlayer dielectric layer, which may lead to device failure. A crack may form in an upper interlayer dielectric layer below the chip pad. However, cracking may extend to interlayer dielectric layers below the upper interlayer dielectric layer.

### SUMMARY

Embodiments may improve the structural strength of an interlayer dielectric layer, which may allow for resilience against relatively larger external loads applied to a chip pad of a semiconductor chip.

In embodiments, a semiconductor chip may include at least one of the following: A semiconductor device formed on a semiconductor substrate. At least one metal wiring layer electrically connected to the semiconductor device, wherein the at least one metal wiring layer is open in the center. At least one interlayer dielectric layer formed over the semiconductor device, wherein the at least one interlayer dielectric layer fills the open portion of the at least one metal wiring layer. A conductive pad formed over the at least one interlayer dielectric layer that may be electrically connected to an external circuit.

In embodiments, conductive vias may be formed between a conductive pad and the at least one metal wiring layer and/or between two or more metal wiring layers. In accordance with embodiments, the conductive vias may be staggered between different via layers.

### DRAWINGS

Example FIG. 1 illustrates a perspective view of wire bonding in a chip pad formed over a semiconductor chip.

Example FIG. 2a illustrates a top view of a chip pad structure.

Example FIG. 2b illustrates a cross-sectional view of a chip pad structure.

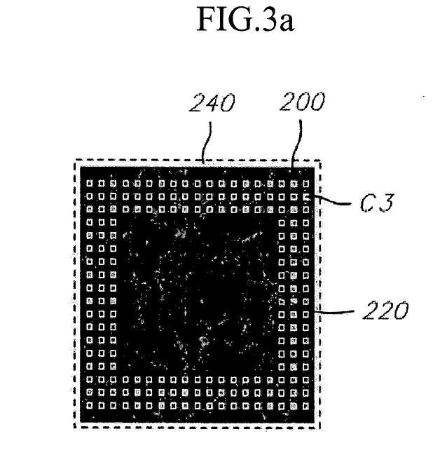

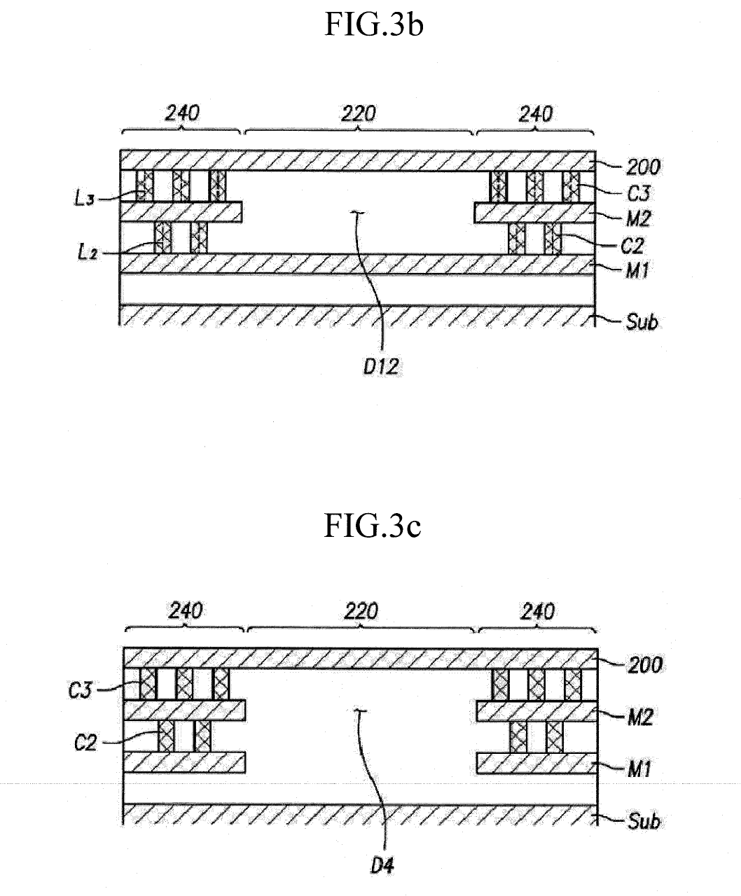

Example FIG. 3a illustrates is a top view of a chip pad with contact plugs formed along the periphery of the chip pad, in accordance with embodiments.

Example FIG. 3b illustrates a cross-sectional view of a conductive pad, conductive vias, and metal wiring layers, in accordance with embodiments.

Example FIG. 3c illustrates a cross-sectional view of a lower structure of a chip pad, according to embodiments.

### DESCRIPTION

In embodiments, a semiconductor chip may include a conductive pad to connect a semiconductor device to an external circuit. At least one semiconductor device may be formed on a semiconductor substrate. At least one metal wiring layer may be formed over at least one semiconductor device. The plurality of metal wiring layers may provide electrical connections to semiconductor devices on the semiconductor chip. At least one metal wiring layer may have a portion that is open in the center of the metal wiring layer. At least one interlayer dielectric layer may be formed between the semiconductor device and the conductive pad. At least one of the interlayer dielectric layers fills an open portion of a metal wiring layer.

In embodiments, a semiconductor device may include a photodiode and/or a MOS transistor if the semiconductor device is part of a CMOS image device. A polysilicon-metal dielectric (PMD) interlayer dielectric layer may be formed over at least one semiconductor device. At least one metal wiring layer and at least one interlayer dielectric layers may be sequentially stacked.

As illustrated in example FIG. 3a, conductive chip pad 200 may have a central portion 220 and a peripheral portion 240, in accordance with embodiments. As illustrated in example FIG. 3b, below chip pad 200 there may be metal wiring layer M2. Metal wiring layer M2 may be formed below the peripheral portion 240 of the chip pad, but open below central portion 220 of chip pad 200, in accordance with embodiments. In embodiments, at least one interlayer dielectric layer D12 is between chip pad 200 and metal wiring layer M2. In embodiments, at least one dielectric layer D12 fills the open area of metal wiring layer M2. There may be a semiconductor substrate SUB below metal wiring layer M1.

Metal wiring layer M1 may be formed below metal wiring layer M2, in accordance with embodiments. In embodiments, metal wiring layer M1 may not have an open area. At least one dielectric layer D12 may be formed between metal wiring layer M1 and metal wiring layer M2, in accordance with embodiments. Contact plugs C3 may electrically connect metal wiring layer M2 and chip pad 200. Contact plugs C2 may electrically connect metal wiring layer M1 and metal wiring layer M2. In embodiments, contact plugs C2 and contact plugs may be staggered. In other words, in embodiments, a center line L3 of contact plugs C3 and a center line L2 of contact plugs C2 may not be collinear. Contact plugs C2 and contact plugs C3 may be formed through at least one interlayer dielectric layer D12 (e.g. through via holes).

In embodiments, a relatively thick portion of at least one interlayer dielectric layer D12 between chip pad 200 and metal wiring layer M1 may maximize the structural integrity and may allow chip pad to withstand a larger load applied to chip pad 200 during testing. In other words, in embodiments, by metal wiring layer M2 being open in the center, at least one interlayer dielectric layer D12 may be thicker under the central portion 220 of chip pad 200. In embodiments, the staggering of contact plugs C2 and contact plugs C3 may maximize the structural integrity and may allow chip pad to withstand a larger load applied to chip pad 200 during testing. Although example FIG. 3b only illustrates one metal wiring layer being open in the center (e.g. metal wiring layer M2), multiple metal wiring layers may be formed over each other with openings to increase the thickness of at least one interlayer dielectric layer, in accordance with embodiments. As illustrated in example FIG. 3c, a lower metal wiring layer (i.e. second metal wiring layer M2) may also be open in the center, in accordance with embodiments. Although example FIG. 3b illustrates contact plugs C2 and contact plugs C3 being staggered, contact plugs C2 and contact plugs C3 may be aligned, in accordance with embodiments.

In embodiments, contact plugs (e.g. contact plugs C2 and contact plugs C3) may only be formed under the peripheral portion 240 of the chip pad 200. Contact plugs C3 may be divided into two regions (i.e. separated under central portion 220) with the at least one interlayer dielectric layer D12 between the two regions. Likewise, contact plugs C2 may be divided into two regions (i.e. separated under central portion 220) with the at least one interlayer dielectric layer D12 between the two regions. Metal wiring layer M2 may be divided into two regions (i.e. separated under central portion 220) with the at least one interlayer dielectric layer D12 between the two regions.

During wire bonding and/or a testing operation, a load may be primarily focused on pad central portion 220. As illustrated in example FIG. 3b, the interlayer dielectric layer D12 formed below the pad central portion 220 is relatively thick (due to the central opening in metal wiring layer M2), which may maximize structural integrity against a relatively large load, in accordance with embodiments. In embodiments, since the at least one interlayer dielectric layer D12 may be relatively thick, cracking of the at least one interlayer dielectric layer D12 can be prevented, thus preventing device failure.

As illustrated in example FIG. 3c, all of the plurality of metal wiring layers (e.g. metal wiring layers M1 and M2) are formed under the pad peripheral portion 240 and open under the pad central portion 220. Accordingly, at least one dielectric interlayer D4 may be formed relatively thick, which may enforce structural integrity against a relatively large external load, in accordance with embodiments.

In embodiments, the structure of at least one interlayer dielectric layer D12 illustrated in example FIG. 3b and at least one interlayer dielectric layer D4 illustrated in example FIG. 3c allow for buffering against the external load applied to conductive pad 200. In embodiments, surface area of pad central portion 220 may be between approximately 25% and approximately 50% of the surface area of conductive pad 200. In embodiments, the length of one side of the pad central portion 220 may be between approximately 50% and approximately 70% of the length of one side of the conductive pad 200. One of ordinary skill in the art will appreciate other relative proportions of the pad central portion 220 with respect to the conductive pad 200. If the area of the pad central portion 220 is too small, a buffering effect may not be optimized. If the area of the pad central portion 220 is too large, a dishing phenomenon may occurs in a chemical mechanical polishing process of a top interlayer dielectric layer.

In embodiments, since a load is substantially concentrated on conductive pad 200 at pad central portion 200, the possibility of cracking of the at least one interlayer dielectric layer (e.g. D12 and/or D4) can be minimized. In embodiments, to reinforce the structural strength of the pad peripheral portion 240, center lines (e.g. L2 and L3) of the contact plugs (e.g. C2 and C3) may not be collinear and may be staggered. For example, example FIG. 3b illustrates the central line L3 of contact plug C3 and center line of contact plug C2 to be along different lines, in accordance with embodiments. In embodiments, the loss regions of the interlayer dielectric layer due to the formation of contact plugs can intersect each other without overlapping each other.

Although embodiments have been described above, it should be understood that numerous other modifications and embodiments can be devised by those skilled in the art that will fall within the spirit and scope of the principles of this disclosure. Various variations and modifications are possible within the scope of the disclosure, the drawings and the appended claims.

What is claimed is:

1. An apparatus comprising:
a semiconductor substrate;
at least one interlayer dielectric layer formed over the semiconductor substrate; and
a conductive pad formed over said at least one interlayer dielectric layer, wherein the conductive pad has a peripheral portion and a central portion, and wherein said at least one interlayer dielectric layer is thicker under the central portion than under the peripheral portion.

2. The apparatus of claim 1, comprising at least one first wiring layer between the conductive pad and the semiconductor substrate, wherein said at least one first wiring layer is formed only under the peripheral portion.

3. The apparatus of claim 2, wherein said at least one interlayer dielectric layer is formed between said at least one first wiring layer and said conductive pad.

4. The apparatus of claim 3, wherein said at least one interlayer dielectric layer is formed between said at least one first wiring layer and the semiconductor substrate.

5. The apparatus of claim 2, wherein:
said at least one first wiring layer comprises a first wiring layer and a second wiring layer; and
said at least one interlayer dielectric layer is formed between the first wiring layer and the second wiring layer.

6. The apparatus of claim 5, comprising:
at least one first contact plug electrically connecting the first wiring layer with the conductive pad; and
at least one second contact plug electrically connecting the first wiring layer with the second wiring layer.

7. The apparatus of claim 6, wherein an axis of said at least one first contact plug and an axis of said at least one second contact plug are not collinear.

8. The apparatus of claim 6, wherein said at least one first contact plug and said at least one second contact plug are formed in said at least one interlayer dielectric layer.

9. The apparatus of claim 2, comprising at least one second wiring layer, wherein said at least one second wiring layer is formed under both the central portion and the peripheral portion.

10. The apparatus of claim 1, wherein a surface area of the central portion is between approximately 25% and approximately 50% of the surface area of the conductive pad.

11. The apparatus of claim 1, wherein the apparatus is comprised in a CMOS image sensor.

12. A method comprising:
forming at least one interlayer dielectric layer over a semiconductor substrate; and
forming a conductive pad over said at least one interlayer dielectric layer, wherein the conductive pad has a peripheral portion and a central portion, and wherein said at least one interlayer dielectric layer is thicker under the central portion than under the peripheral portion.

13. The method of claim 12, comprising forming at least one first wiring layer over the semiconductor substrate, wherein said at least one first wiring layer is formed only under the peripheral portion.

14. The method of claim 13, wherein said at least one interlayer dielectric layer is formed between said at least one first wiring layer and said conductive pad.

15. The method of claim 14, wherein said at least one interlayer dielectric layer is formed between said at least one first wiring layer and the semiconductor substrate.

16. The method of claim 13, wherein:
said at least one first wiring layer comprises a first wiring layer and a second wiring layer; and
said at least one interlayer dielectric layer is formed between the first wiring layer and the second wiring layer.

17. The method of claim 16, comprising:
forming at least one first contact plug electrically connecting the first wiring layer with the conductive pad; and
forming at least one second contact plug electrically connecting the first wiring layer with the second wiring layer.

18. The method of claim 17, wherein an axis of said at least one first contact plug and an axis of said at least one second contact plug are not collinear.

19. The method of claim 17, wherein said at least one first contact plug and said at least one second contact plug are formed in said at least one interlayer dielectric layer.

20. The method of claim 13, comprising forming at least one second wiring layer, wherein said at least one second wiring layer is formed under both the central portion and the peripheral portion.

21. The method of claim 12, wherein a surface area of the central portion is between approximately 25% and approximately 50% of the surface area of the conductive pad.

22. The method of claim 12, wherein the conductive pad is comprised in a CMOS image sensor.
